(19) United States
(12) Patent Application Publication
(10) Pub. No.: US 2026/0182125 A1
(43) Pub. Date: Jun. 25, 2026

(54) DISPLAY APPARATUS AND MANUFACTURING METHOD THEREOF

(71) Applicant: AUO Corporation, Hsinchu City (TW)

(72) Inventors: Chih-Wen Lu, Hsinchu City (TW); Yun Cheng, Hsinchu City (TW); Hao-An Chuang, Hsinchu City (TW)

(73) Assignee: AUO Corporation, Hsinchu City (TW)

(21) Appl. No.: 19/204,625

(22) Filed: May 12, 2025

(30) Foreign Application Priority Data
Dec. 23, 2024 (TW) 113150134

(51) Int. Cl. H10H 29/853; H01L 25/075; H10H 29/01; H10H 29/02; H10H 29/24; H10H 29/85

(52) U.S. Cl. CPC H10H 29/853; H10H 29/02; H10H 29/0362; H10H 29/0364; H10H 29/24; H10H 29/857; H10W 90/00

(57) ABSTRACT

A display apparatus includes a driving backplane, light-emitting elements and residual glue structures. The light emitting elements are bonded to the driving backplane. Each of the residual glue structures covers at least one portion of a side wall of a corresponding light-emitting element. In a top view of the display apparatus, a residual glue structure has an edge beyond a light-emitting element, and the edge is irregular. In addition, a manufacturing method of the display apparatus is also provided.

### CROSS-REFERENCE TO RELATED APPLICATION

This application claims the priority benefit of Taiwan application serial no. 113150134, filed on Dec. 23, 2024. The entirety of the above-mentioned patent application is hereby incorporated by reference herein and made a part of this specification.

### BACKGROUND

### Technical Field

The disclosure relates to a display apparatus and a manufacturing method thereof.

### Description of Related Art

A light-emitting diode display panel includes a driving backplane and a plurality of light-emitting diode devices transferred onto the driving backplane. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

In the manufacturing process of a light-emitting diode display panel, a picking up head is required to transfer a plurality of light-emitting diode elements of a temporary storage light-emitting element substrate to a driving backplane. However, there is a risk that residual glue will adhere to the solder of the LED component, which may cause the LED component to not be picked up successfully.

### SUMMARY

The present disclosure provides a display apparatus with good performance.

The present disclosure provides a manufacturing method of a display apparatus, which can manufacture a display apparatus with good performance.

A display apparatus of the present disclosure includes a driving backplane, light-emitting elements and residual glue structures. The light-emitting elements are bonded to the driving backplane and electrically connected to the driving backplane. Each of the residual glue structures covers at least a portion of a side wall of a corresponding light-emitting element of the light-emitting elements. A residual glue structure of the residual glue structures covers a light-emitting element of the light-emitting elements. In a top view of the display apparatus, the residual glue structure has an edge that exceeds the light-emitting element, and the edge is irregular.

A manufacturing method of a display apparatus of the present disclosure includes following steps: providing a temporary storage light-emitting element substrate, wherein the temporary storage light-emitting element substrate comprises a base, an adhesive layer, light-emitting elements and residual glue patterns, the adhesive layer is disposed on the base, the light-emitting elements are disposed on the adhesive layer, the light-emitting elements respectively have a plurality of top surfaces facing away from the base, and the residual glue patterns are respectively disposed on the top surfaces of the light-emitting elements; using a picking up head to pick up the light-emitting elements and the residual glue patterns from the base of the temporary storage light-emitting element substrate; using the picking up head, transferring the light-emitting elements and the residual glue patterns onto a driving backplane; when the picking up head presses the residual glue patterns and the light-emitting elements toward the driving backplane, a laser bonding process is performed to electrically connect the light-emitting elements to the driving backplane and melt the residual glue patterns, wherein the melted residual glue patterns are solidified into residual glue structures; and forming a molding layer on the driving backplane to cover the residual glue structures.

### BRIEF DESCRIPTION OF THE DRAWINGS

FIGS. 1A to 1F are cross-sectional diagrams showing the manufacturing process of a display apparatus according to an embodiment of the disclosure.

FIGS. 2A to 2C show the detailed process of transferring the light-emitting element of an embodiment of the disclosure to a driving backplane and bonding it to the driving backplane using a laser bonding process.

FIG. 3 shows a light-emitting element and a residual glue structure of a display apparatus according to an embodiment of the present disclosure.

FIG. 4 shows another light-emitting element and another residual glue structure of the display apparatus according to an embodiment of the disclosure.

FIG. 5 is a cross-sectional schematic diagram of a display apparatus according to another embodiment of the disclosure.

FIG. 6 is a cross-sectional schematic diagram of a display apparatus according to another embodiment of the disclosure.

FIG. 7 is a cross-sectional schematic diagram of a display apparatus according to yet another embodiment of the disclosure.

FIG. 8 is a cross-sectional schematic diagram of a display apparatus according to an embodiment of the disclosure.

FIG. 9 is a cross-sectional schematic diagram of a display apparatus according to another embodiment of the disclosure.

FIG. 10 is a cross-sectional schematic diagram of a display apparatus according to another embodiment of the disclosure.

FIG. 11 is a cross-sectional schematic diagram of a display apparatus according to yet another embodiment of the disclosure.

FIG. 12 is a cross-sectional diagram of a display apparatus according to an embodiment of the disclosure.

FIG. 13 is a cross-sectional schematic diagram of a display apparatus according to another embodiment of the disclosure.

FIG. 14 is a cross-sectional schematic diagram of a display apparatus according to yet another embodiment of the disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

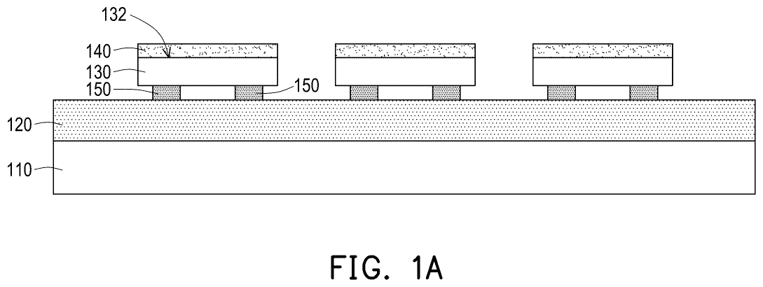

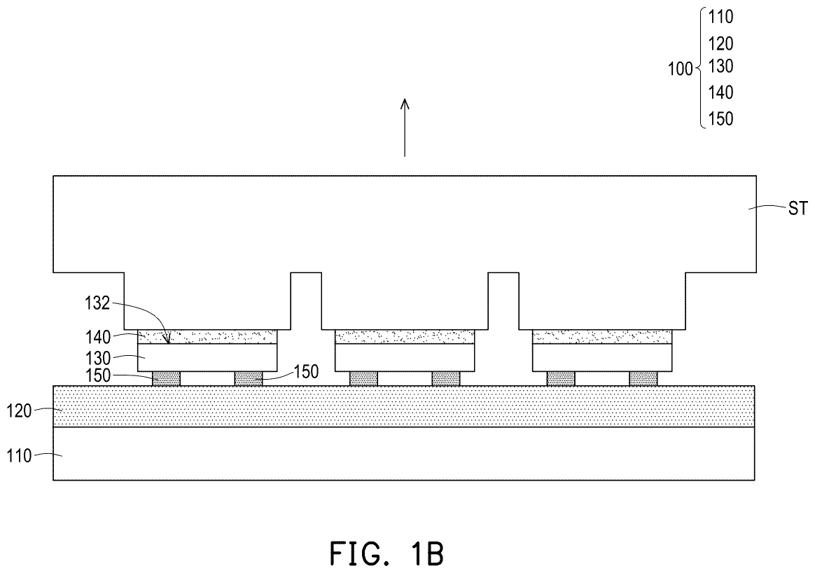

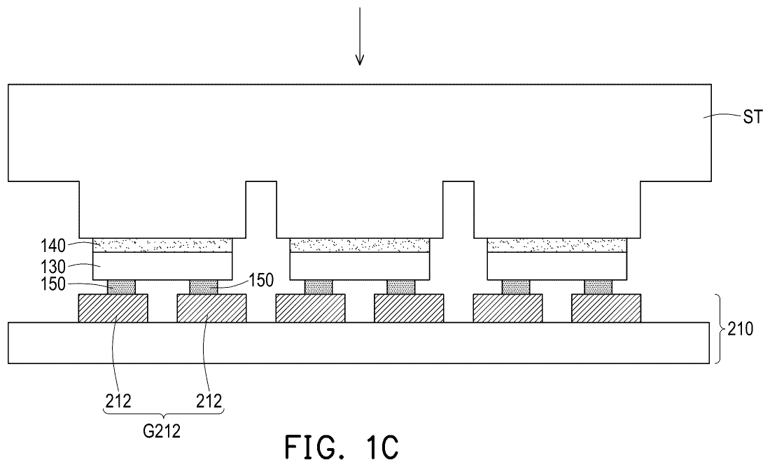

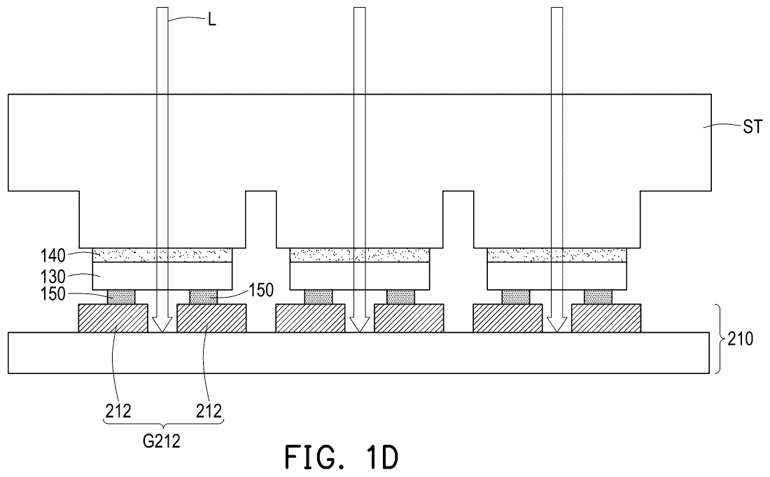

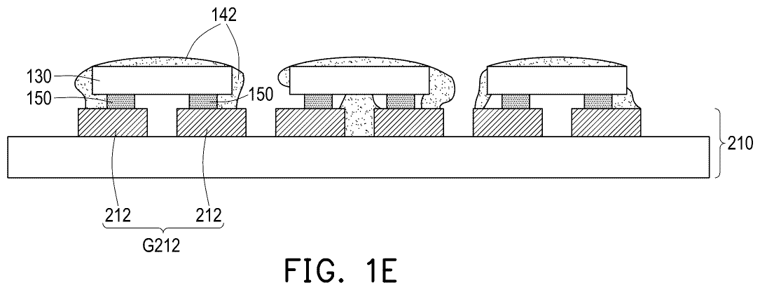

FIGS. 1A to 1F are cross-sectional diagrams showing the manufacturing process of a display apparatus according to an embodiment of the disclosure. Referring to FIG. 1A, first, a temporary storage light-emitting element substrate 100 is provided. The temporary storage light-emitting element substrate 100 includes a base 110, an adhesive layer 120, light-emitting elements 130 and residual glue patterns 140. The adhesive layer 120 is disposed on the base 110. In some embodiments, the adhesive layer 120 may completely cover the surface of the base 110, but the disclosure is not limited thereto. Light-emitting elements 130 are disposed on the adhesive layer 120. The adhesive layer 120 is located between the light-emitting elements 130 and the base 110. The light-emitting elements 130 respectively have top surfaces 132 facing away from the base 110. The residual glue patterns 140 are separated from each other and are respectively disposed on the top surfaces 132 of the light-emitting elements 130.

Each of the light-emitting element 130 may include a first semiconductor layer (not shown), a second semiconductor layer (not shown), an active layer (not shown) disposed between the first semiconductor layer and the second semiconductor layer, and a plurality of electrodes (not shown) electrically connected to the first semiconductor layer and the second semiconductor layer, respectively. In some embodiments, a plurality of electrodes of the light-emitting element 130 may be selectively located on the same side of the active layer and facing the adhesive layer 120, but the disclosure is not limited thereto. In some embodiments, the light-emitting element 130 is, for example, a micro light emitting diode (μLED), but the disclosure is not limited thereto.

In some embodiments, the temporary storage light-emitting element substrate 100 may further include solders 150, which are respectively disposed on electrodes of the light-emitting elements 130. In some embodiments, the solders 150 may be located between the adhesive layer 120 and the light-emitting element 130. For example, in some embodiments, a material of solder 150 may include tin (Sn), but the disclosure is not limited thereto.

Referring to FIG. 1B, a picking up head ST is then used to pick up light-emitting elements 130 and residual glue patterns 140 from a base 110 of the temporary storage light-emitting element substrate 100. Specifically, in some embodiments, the picking up head ST first contacts the residual glue patterns 140 to be temporarily connected to the residual glue patterns 140; then, the picking up head ST is moved away from the base 110 to simultaneously separate the residual glue patterns 140, the light-emitting elements 130, and the solders 150 from the adhesive layer 120.

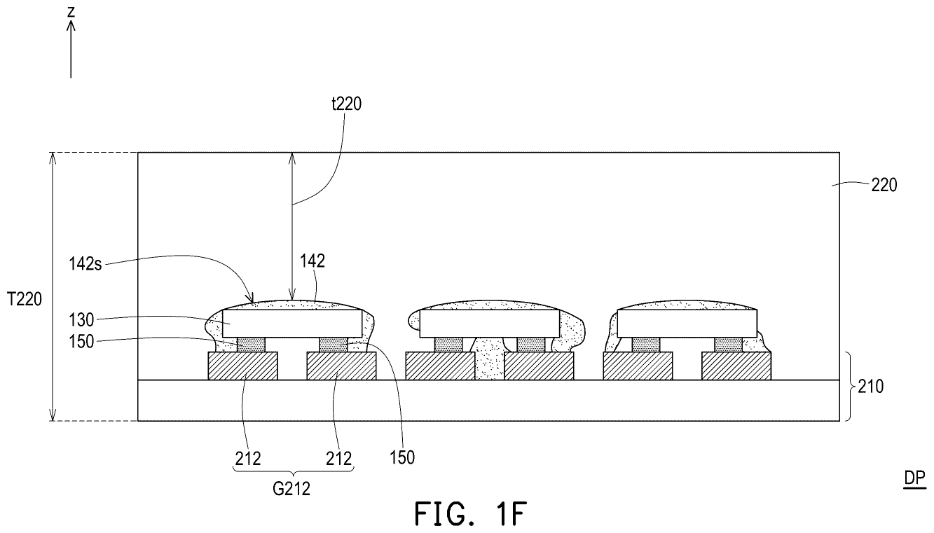

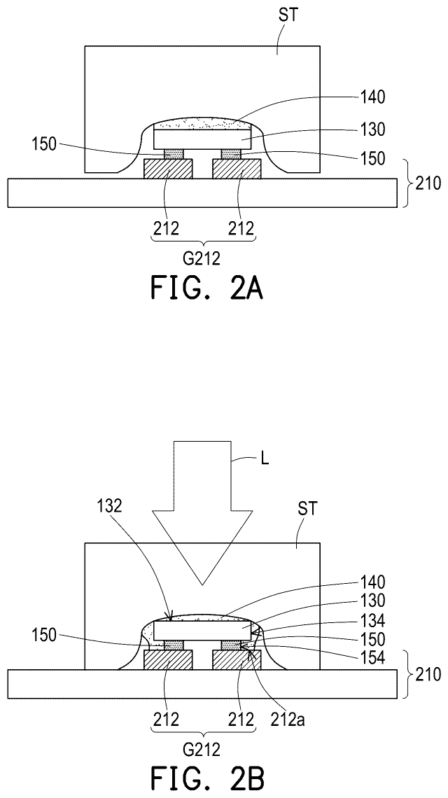

FIGS. 2A to 2C show the detailed process of transferring the light-emitting element of an embodiment of the disclosure to a driving backplane and bonding it to the driving backplane using a laser bonding process. FIG. 2A to FIG. 2C correspond to FIG. 1C to FIG. 1E.

Referring to FIG. 1C and FIG. 2A, a picking up head ST is then used to transfer the light-emitting elements 130 and the glue patterns 140 onto the driving backplane 210. In some embodiments, driving backplane 210 may include a carrier base (not shown), pixel driving circuits (not shown) and pad groups G212, wherein the pixel driving circuits are disposed on the carrier base, and the plurality of pad groups G212 are respectively electrically connected to the plurality of pixel driving circuits. In some embodiments, each of the pad groups G212 may include pads 212 that are structurally separated from each other. In some embodiments, during the process of transferring the light-emitting elements 130 and the residual glue patterns 140 onto the driving backplane 210, the solders 150 on the light-emitting elements 130 are aligned with the pads 212 respectively, and the picking up head ST causes the solders 150 to contact and press down the pads 212 respectively.

Referring to FIG. 1D, FIG. 1E, FIG. 2B and FIG. 2C, then, when the picking up head ST presses the residual glue patterns 140 and the light-emitting elements 130 toward the driving backplane 210, a laser bonding process is performed to electrically connect the light-emitting elements 130 to the driving backplane 210 and melt the residual glue patterns 140.

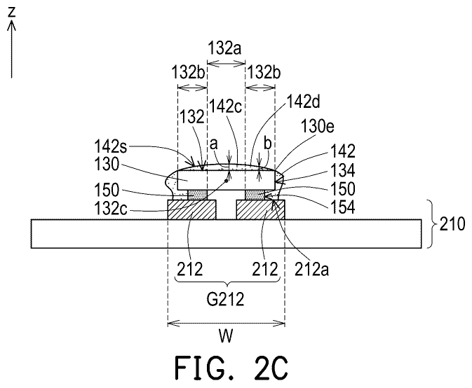

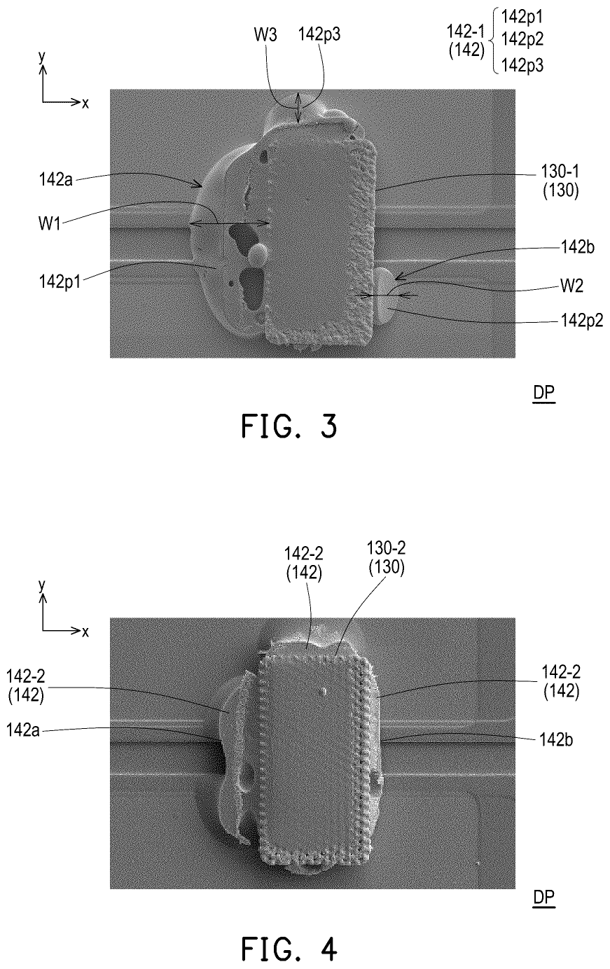

Specifically, in some embodiments, the laser beam L used in the laser bonding process at least irradiates the light-emitting element 130 and the residual glue pattern 140 on the light-emitting element 130, so that the residual glue pattern 140 and the solder 150 respectively located on the upper and lower sides of the light-emitting element 130 are heated and melted. The molten solder 150 solidifies after cooling down, thereby fixing the light-emitting element 130 and the pad 212. The melted residual glue pattern 140 will overflow from the top surface 132 of the light-emitting element 130 to the outside of the light-emitting element 130. When the molten residual glue pattern 140 cools down, it solidifies to form a residual glue structure 142. FIG. 3 shows a light-emitting element and a residual glue structure of a display apparatus according to an embodiment of the present disclosure. FIG. 4 shows another light-emitting element and another residual glue structure of the display apparatus according to an embodiment of the disclosure. Referring to FIG. 3 and FIG. 4, in the top view, it can be found that the edges 142a and 142b of the residual glue structures 142 are irregular.

Referring to FIGS. 2A to 2C, in some embodiments, a portion of the residual glue pattern 140 irregularly overflows onto the side wall 134 of the light-emitting element 130 (or, the periphery of the light-emitting element 130) and the side wall 154 of the solder 150, and finally flows onto the top surface 212a of the pad 212 to form a protective microstructure. The protective microstructure (i.e., the residual glue structure 142) can reduce the risk of the light-emitting element 130 being pushed away during the subsequent packaging process.

Referring to FIGS. 2A to 2C, in some embodiments, the shape of the melted residual glue pattern 140 is deformed due to being squeezed by the picking up head ST, so that the melted residual glue pattern 140 forms an arc shape on the top surface 132 (or the light emitting surface) of the light-emitting element 130. The residual glue pattern 140 with an arc shape can be solidified into a residual glue structure 142 after cooling down. Inheriting the arc shape of the residual glue pattern 140, the residual glue structure 142 generally presents a micro flat convex lens structure with light-gathering properties, which can increase the brightness of the light-emitting element 130.

Referring to FIG. 1F, a molding layer 220 is then formed on the driving backplane 210 to cover the residual glue structures 142. At this point, the display apparatus DP is completed. The molding layer 220 is disposed on the driving backplane 210 and covers the residual glue structure 142. In some embodiments, the molding layer 220 may selectively be a transparent film layer, and the molding layer 220 may cover the top surface 132 (or light-emitting surface) of the light-emitting element 130, but the disclosure is not limited thereto. For example, in some embodiments, the thickness T220 of the molding layer 220 is about 30 μm, and the thickness t220 of the portion of the molding layer 220 located on the top surface 132 of the light-emitting element 130 is about 20 μm, but the disclosure is not limited thereto.

Referring to FIG. 1F, the display apparatus DP includes a driving backplane 210, light-emitting elements 130, and residual glue structures 142. The light-emitting elements 130 are bonded to the driving backplane 210 and are electrically connected to the driving backplane 210. The residual glue structures 142 cover the light-emitting elements 130 respectively. Referring to FIG. 1D, FIG. 1E, FIG. 1F, FIG. 3 and FIG. 4, it is worth noting that the residual glue structure 142 is formed by melting and then solidifying the residual glue pattern 140 disposed on the top surface 132 of the light-emitting element 130 during the manufacturing process of the display apparatus DP. Therefore, in the top view of the display apparatus DP, the residual glue structure 142 has edges 142a and 142b that extend beyond the light-emitting element 130, and the edges 142a and 142b are irregular.

Referring to FIG. 3, in some embodiments, the residual glue structure 142 may have an edge 142a and an edge 142b that extend beyond the light-emitting element 130 and are located at opposite sides of the light-emitting element 130, and the shape of the edge 142a is different from the shape of the edge 142b. In some embodiments, in a top view, the residual glue structure 142 may include a first portion 142p1 and a second portion 142p2, the first portion 142p1 and the second portion 142p2 are located outside the light-emitting element 130 and are located on opposite sides of the light-emitting element 130, respectively, the first portion 142p1 and the second portion 142p2 of the residual glue structure 142 have a first maximum width W1 and a second maximum width W2 in a direction×parallel to the driving backplane 210, respectively, and the first maximum width W1 is different from the second maximum width W2.

In some embodiments, the first portion 142p1 and the second portion 142p2 of the residual glue structure 142 may be located on the left and right sides of the light-emitting element 130, respectively. The residual glue structure 142 may also include a third portion 142p3 located on the upper side of the light-emitting element 130. The third portion 142p3 has a third maximum width W3 in direction y. The first maximum width W1, the second maximum width W2 and the third maximum width W3 may be different from each other, wherein the direction y is parallel to the driving backplane 210 and perpendicular to the direction x. For example, in some embodiments, W1=14.6 μm, W3=14.1 μm, but the disclosure is not limited thereto. In some embodiments, the material of the residual glue structure 142 may be transparent or translucent silicone, but the disclosure is not limited thereto.

Referring to FIG. 3 and FIG. 4, in some embodiments, the light-emitting elements 130 of the display apparatus DP may include a first light-emitting element 130-1 and a second light-emitting element 130-2, and the residual glue structures 142 of the display apparatus DP may include a first residual glue structure 142-1 and a second residual glue structure 142-2. The first residual glue structure 142-1 and the second residual glue structure 142-2 cover the first light-emitting element 130-1 and the second light-emitting element 130-2 respectively. In the top view of the display apparatus DP, the shape of the first residual glue structure 142-1 and the shape of the second residual glue structure 142-2 may be different.

Referring to FIG. 1F, in some embodiments, the display apparatus DP further includes a solder 150 and a molding layer 220. The solder 150 is disposed between the light-emitting element 130 and the pad 212 of the driving backplane 210. The light-emitting element 130 is bonded to the pad 212 of the driving backplane 210 through the solder 150. FIG. 2C shows a driving backplane, a solder, a light-emitting element, and a residual glue structure according to an embodiment of the disclosure. Referring to FIG. 1F and FIG. 2C, in some embodiments, at least one residual glue structure 142 may contact the side wall 134 of the light-emitting element 130 and the side wall 154 of the solder 150 and extend to the top surface 212a of the pad 212.

Referring to FIG. 1F and FIG. 2C, in some embodiments, the light-emitting element 130 has a top surface 132 facing away from the driving backplane 210. The top surface 132 of the light-emitting element 130 includes a middle area 132a and an edge area 132b. The middle area 132a overlaps with the geometric center 130c of the light-emitting element 130. The edge area 132b is disposed between the middle area 132a and the edge 130e of the light-emitting element 130. A portion 142c of the residual glue structure 142 disposed on the middle area 132a has a first thickness a, and a portion 142d of the residual glue structure 142 disposed on the edge area 132b has a second thickness b, and the first thickness a is greater than the second thickness b. That is, in some embodiments, the thickness of the residual glue structure 142 becomes thinner as it approaches the edge 130e of the light-emitting element 130. For example, in some embodiments, the first thickness a may be in the range of 0.3 μm to 0.7 μm, and the aspect ratio of the residual glue structure 142 (ie, the ratio of the first thickness a to the width W of the residual glue structure 142 in the direction x) may be in the range of 0.005 to 0.02, but the disclosure is not limited thereto.

Referring to FIGS. 1F and 2C, in some embodiments, a portion of the residual glue structure 142 has a surface 142 s facing away from the light-emitting element 130, and the surface 142 s includes a curved surface protruding in a direction z away from the light-emitting element 130. In some embodiments, the curved surface is, for example, an arc surface, but the disclosure is not limited thereto.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

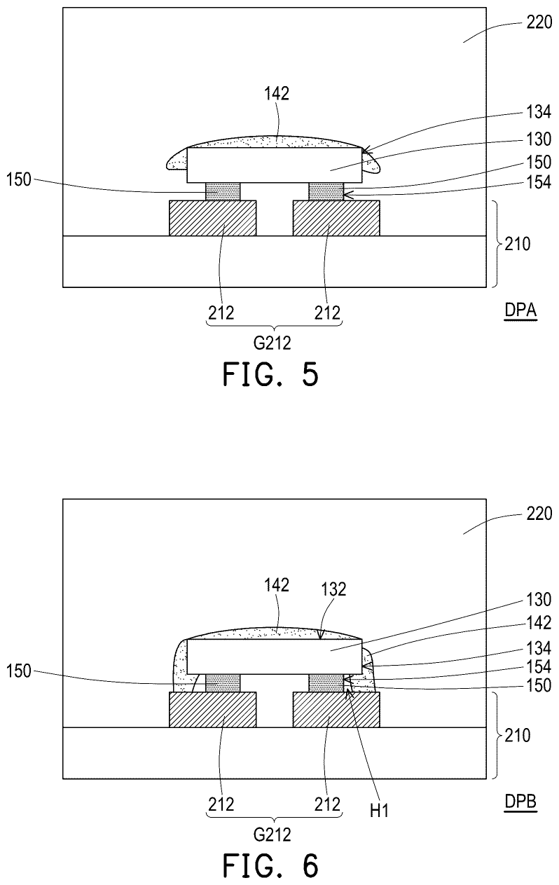

FIG. 5 is a cross-sectional schematic diagram of a display apparatus according to another embodiment of the disclosure. The display apparatus DPA of FIG. 5 is similar to the display apparatus DP of FIG. 1F, but the difference between the two is that the residual glue structures 142 of the two are not completely the same in appearance. Referring to FIG. 5, specifically, in this embodiment, the residual glue structure 142 may cover the top surface 132 and the side wall 134 of the light-emitting element 130 but does not extend to the side wall 154 of the solder 150 and the pad 212.

FIG. 6 is a cross-sectional schematic diagram of a display apparatus according to another embodiment of the disclosure. The display apparatus DPB of FIG. 6 is similar to the display apparatus DP of FIG. 1F, but the difference between the two is that the residual glue structures 142 of the two are different in appearance. Referring to FIG. 6, specifically, in this embodiment, the residual glue structure 142 may cover the top surface 132 and the side wall 134 of the light-emitting element 130 and extend onto the pad 212, but the residual glue structure 142 does not completely cover the side wall 154 of the solder 150. At least a portion of the residual glue structure 142, the solder 150, the light-emitting element 130, and the pad 212 may surround the porosity H1, and a portion of the molding layer 220 may be filled into the porosity H1 through a capillary phenomenon.

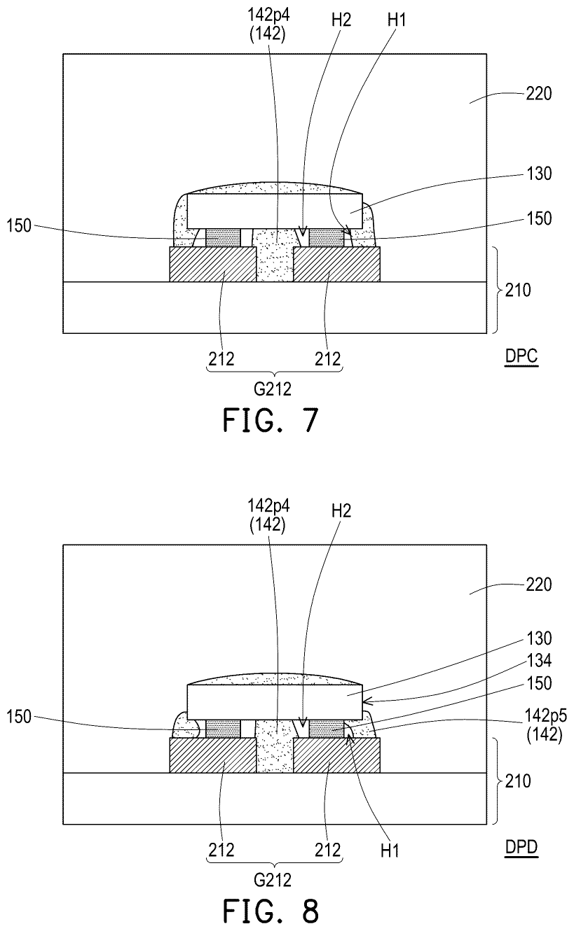

FIG. 7 is a cross-sectional schematic diagram of a display apparatus according to yet another embodiment of the disclosure. The display apparatus DPC of FIG. 7 is similar to the display apparatus DPB of FIG. 6, but the difference between the two is that the residual glue structures 142 of the two are not completely the same in appearance. Referring to FIG. 7, specifically, in the present embodiment, a portion 142p4 of the residual glue structure 142 is disposed between the pads 212 and between the solders 150. The portion 142p4 of the residual glue structure 142, the solders 150, the light-emitting element 130 and the pads 212 surround the porosity H2. A portion of the molding layer 220 may be filled into the porosity H2 through a capillary phenomenon.

FIG. 8 is a cross-sectional schematic diagram of a display apparatus according to an embodiment of the disclosure. The display apparatus DPD of FIG. 8 is similar to the display apparatus DPC of FIG. 7, but the difference between the two is that the residual glue structures 142 of the two are not completely the same in appearance. Referring to FIG. 8, specifically, in this embodiment, a portion of the residual glue structure 142 is concentrated toward the pad 212 and does not cover most of the area of the side wall 134 of the light-emitting element 130.

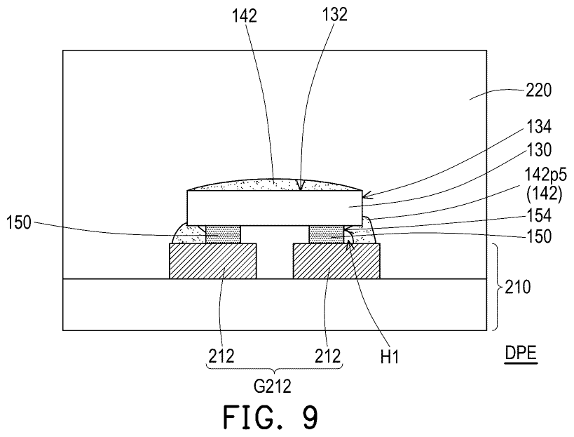

FIG. 9 is a cross-sectional schematic diagram of a display apparatus according to another embodiment of the disclosure. The display apparatus DPE of FIG. 9 is similar to the display apparatus DPB of FIG. 6, but the difference between the two is that the residual glue structures 142 of the two are not completely the same in appearance. Referring to FIG. 9, specifically, in this embodiment, a portion 142p5 of the residual glue structure 142 is concentrated toward the pad 212 and does not cover most of the area of the side wall 134 of the light-emitting element 130.

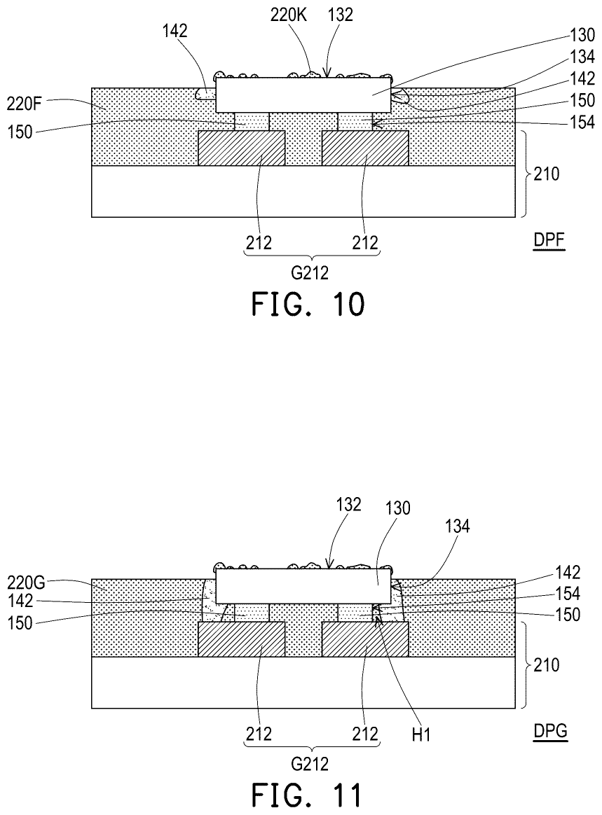

FIG. 10 is a cross-sectional schematic diagram of a display apparatus according to another embodiment of the disclosure. The display apparatus DPF of FIG. 10 is similar to the display apparatus DPA of FIG. 5, and the difference between the two is that a molding layer 220F of FIG. 10 is different from the molding layer 220 of FIG. 5. Referring to FIG. 10, specifically, in this embodiment, the material of the molding layer 220F is a light-absorbing material, and the molding layer 220F is lower than the top surface 132 (ie, the light-emitting surface) of the light-emitting element 130. In some embodiments, some molding layer 220K may remain on the top surface 132 of the light-emitting element 130. In some embodiments, the molding layer 220F is, for example, a black glue, but the disclosure is not limited thereto.

FIG. 11 is a cross-sectional schematic diagram of a display apparatus according to yet another embodiment of the disclosure. The display apparatus DPG of FIG. 11 is similar to the display apparatus DPB of FIG. 6, and the difference between the two is that a molding layer 220G of FIG. 11 is different from the molding layer 220 of FIG. 6. Referring to FIG. 11, specifically, in this embodiment, the material of the molding layer 220G is a light absorbing material, and the molding layer 220G is lower than the top surface 132 (ie, the light emitting surface) of the light-emitting element 130.

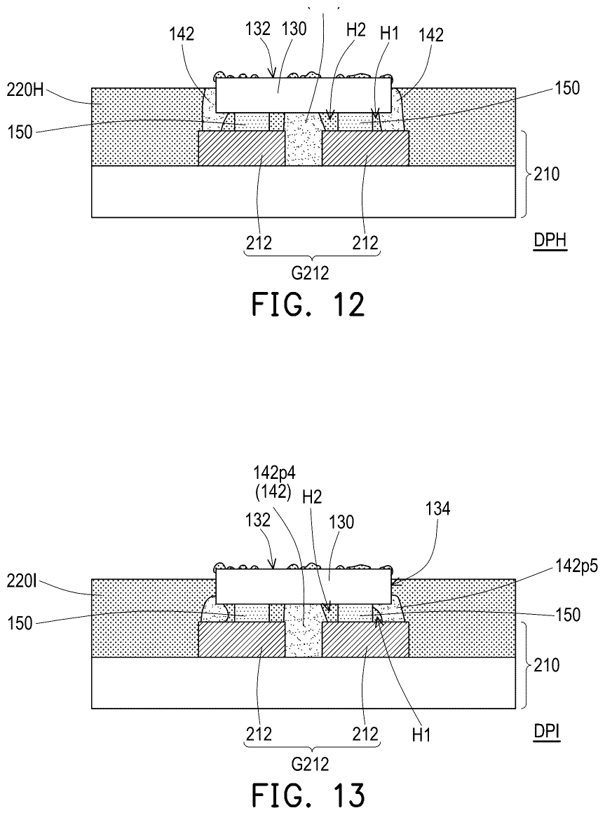

FIG. 12 is a cross-sectional diagram of a display apparatus according to an embodiment of the disclosure. The display apparatus DPH of FIG. 12 is similar to the display apparatus DPC of FIG. 7, and the difference between the two is that a molding layer 220H of FIG. 12 is different from the molding layer 220 of FIG. 7. Referring to FIG. 12, specifically, in this embodiment, the material of the molding layer 220H is a light absorbing material, and the molding layer 220H is lower than the top surface 132 (ie, the light emitting surface) of the light-emitting element 130.

FIG. 13 is a cross-sectional schematic diagram of a display apparatus according to another embodiment of the disclosure. The display apparatus DPI of FIG. 13 is similar to the display apparatus DPD of FIG. 8, and the difference between the two is that a molding layer 220I of FIG. 13 is different from the molding layer 220 of FIG. 8. Referring to FIG. 13, specifically, in this embodiment, the material of the molding layer 220I is a light absorbing material, and the molding layer 220I is lower than the top surface 132 (ie, the light emitting surface) of the light-emitting element 130.

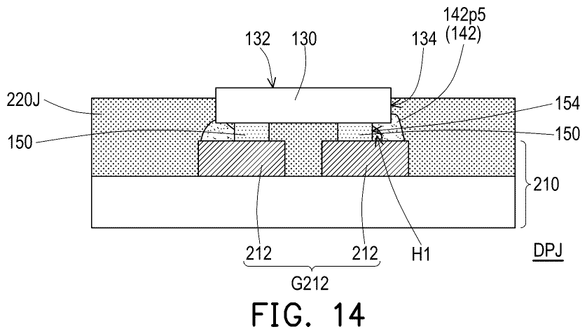

FIG. 14 is a cross-sectional schematic diagram of a display apparatus according to yet another embodiment of the disclosure. The display apparatus DPJ of FIG. 14 is similar to the display apparatus DPE of FIG. 9, and the difference between the two is that a molding layer 220J of FIG. 14 is different from the molding layer 220 of FIG. 9. Referring to FIG. 14, specifically, in this embodiment, the material of the molding layer 220J is a light-absorbing material, and the molding layer 220J is lower than the top surface 132 (ie, the light-emitting surface) of the light-emitting element 130. In some embodiments, there may be no molding layer 220 remaining on the top surface 132 of the light-emitting element 130.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus comprising:
a driving backplane;
light-emitting elements bonded to the driving backplane and electrically connected to the driving backplane; and
residual glue structures, wherein each of the residual glue structures covers at least a portion of a side wall of a corresponding light-emitting element of the light-emitting elements;
wherein a residual glue structure of the residual glue structures covers a light-emitting element of the light-emitting elements; in a top view of the display apparatus, the residual glue structure has an edge that exceeds the light-emitting element, and the edge is irregular.

2. The display apparatus according to claim 1, further comprising:
a solder disposed between the light-emitting element and a pad of the driving backplane, wherein the light-emitting element is bonded to the pad of the driving backplane through the solder, and the residual glue structure contacts a side wall of the light-emitting element and a side wall of the solder and extends onto the pad; and
a molding layer disposed on the driving backplane and covers the residual glue structure.

3. The display apparatus according to claim 1, further comprising:
a solder disposed between the light-emitting element and a pad of the driving backplane, wherein the light-emitting element is bonded to the pad of the driving backplane through the solder, and the residual glue structure contacts a side wall of the light-emitting element and a side wall of the solder and extends onto the pad; and
a molding layer disposed on the driving backplane and covers the residual glue structure;
wherein at least a portion of the residual glue structure, the solder, the light-emitting element, and the pad surround a porosity.

4. The display apparatus according to claim 3, wherein a portion of the molding layer is filled into the porosity.

5. The display apparatus according to claim 1, further comprising:
solders disposed between the light-emitting element and pads of the driving backplane, wherein the light-emitting element is bonded to the pads of the driving backplane through the solders, a portion of the residual glue structure is disposed between the pads and between the solders, and the portion of the residual glue structure, the solders, the light-emitting element and the pads surround a porosity.

6. The display apparatus according to claim 5, further comprising:
A molding layer disposed on the driving backplane and covers the residual glue structure, wherein a portion of the molding layer is filled into the porosity.

7. The display apparatus according to claim 1, wherein the light-emitting element has a top surface facing away from the driving backplane, the top surface of the light-emitting element comprises a middle area and an edge area, the middle area overlaps a geometric center of the light-emitting element, the edge area is disposed between the middle area and an edge of the light-emitting element, a portion of the residual glue structure disposed on the middle area has a first thickness, a portion of the residual glue structure disposed on the edge area has a second thickness, and the first thickness is greater than the second thickness.

8. The display apparatus according to claim 1, wherein the light-emitting element has a top surface facing away from the driving backplane, a portion of the residual glue structure is disposed on the top surface of the light-emitting element, the portion of the residual glue structure has a surface facing away from the light-emitting element, and the surface comprises a curved surface protruding in a direction away from the light-emitting element.

9. The display apparatus according to claim 1, wherein in a top view of the display apparatus, the residual glue structure comprises a first portion and a second portion, the first portion and the second portion are located outside the light-emitting element and are respectively located on two opposite sides of the light-emitting element, the first portion and the second portion of the residual glue structure respectively have a first maximum width and a second maximum width in a direction parallel to the driving backplane, and the first maximum width is different from the second maximum width.

10. The display apparatus according to claim 1, wherein the light-emitting elements comprise a first light-emitting element and a second light-emitting element, the residual glue structures comprise a first residual glue structure and a second residual glue structure, the first residual glue structure and the second residual glue structure respectively cover the first light-emitting element and the second light-emitting element; in a top view of the display apparatus, a shape of the first residual glue structure is different from a shape of the second residual glue structure.

11. The display apparatus according to claim 1, wherein the residual glue structure further covers at least a portion of a top surface of the corresponding light-emitting element.

12. A manufacturing method of a display apparatus comprising:
providing a temporary storage light-emitting element substrate, wherein the temporary storage light-emitting element substrate comprises a base, an adhesive layer, light-emitting elements and residual glue patterns, the adhesive layer is disposed on the base, the light-emitting elements are disposed on the adhesive layer, the light-emitting elements respectively have a plurality of top surfaces facing away from the base, and the residual glue patterns are respectively disposed on the top surfaces of the light-emitting elements;
using a picking up head to pick up the light-emitting elements and the residual glue patterns from the base of the temporary storage light-emitting element substrate;
using the picking up head, transferring the light-emitting elements and the residual glue patterns onto a driving backplane;
when the picking up head presses the residual glue patterns and the light-emitting elements toward the driving backplane, a laser bonding process is performed to electrically connect the light-emitting elements to the driving backplane and melt the residual glue patterns, wherein the melted residual glue patterns are solidified into residual glue structures; and
forming a molding layer on the driving backplane to cover the residual glue structures.

13. The manufacturing method of the display apparatus according to claim 12, wherein a residual glue structure of the residual glue structures covers a light-emitting element of the light-emitting elements; in a top view of the display apparatus, the residual glue structure has an edge that exceeds the light-emitting element, and the edge is irregular.

14. The manufacturing method of the display apparatus according to claim 13, wherein at least a portion of the residual glue structure, a solder, the light-emitting element, and a pad of the driving backplane surround a porosity, and a portion of the molding layer is filled into the porosity.

15. The manufacturing method of the display apparatus according to claim 13, wherein a portion of the residual glue structure is disposed between pads of the driving backplane and between solders, and the portion of the residual glue structure, the solders, the light-emitting element, and the pads surround a porosity, and a portion of the molding layer is filled into the porosity.

16. The manufacturing method of the display apparatus according to claim 13, wherein the light-emitting element has a top surface facing away from the driving backplane, the top surface of the light-emitting element comprises a middle area and an edge area, the middle area overlaps a geometric center of the light-emitting element, the edge area is disposed between the middle area and an edge of the light-emitting element, a portion of the residual glue structure disposed on the middle area has a first thickness, a portion of the residual glue structure disposed on the edge area has a second thickness, and the first thickness is greater than the second thickness.

17. The manufacturing method of the display apparatus according to claim 13, wherein the light-emitting element has a top surface facing away from the driving backplane, a portion of the residual glue structure is disposed on the top surface of the light-emitting element, the portion of the residual glue structure has a surface facing away from the light-emitting element, and the surface comprises a curved surface protruding in a direction away from the light-emitting element.

18. The manufacturing method of the display apparatus according to claim 12, wherein in a top view of the display apparatus, the residual glue structure comprises a first portion and a second portion, the first portion and the second portion are located outside the light-emitting element and are respectively located on two opposite sides of the light-emitting element, the first portion and the second portion of the residual glue structure respectively have a first maximum width and a second maximum width in a direction parallel to the driving backplane, and the first maximum width is different from the second maximum width.
